(19) United States
(12) Patent Application Publication
(10) Pub. No.: US 2006/0096534 A1
(43) Pub. Date: May 11, 2006

(54) Apparatus for depositing thin film on wafer

(76) Inventors: Hong Joo Lim, Pyungtaek-city (KR); Sahng Kyu Lee, Pyungtaek-city (KR); Tae Wook Seo, Pyungtaek-city (KR); Ho Seung Chang, Pyungtaek-city (KR)

Correspondence Address: CANTOR COLBURN, LLP, 55 GRIFFIN ROAD SOUTH, BLOOMFIELD, CT, 06002, US

(21) Appl. No.: 11/264,993

(22) Filed: Nov. 2, 2005

(30) Foreign Application Priority Data
Nov. 6, 2004 (KR) 10-2004-0090130

(51) Int. Cl. C23C 16/00

(52) U.S. Cl. 118/715; 118/726

(57) ABSTRACT

A thin film deposition apparatus that can effectively use a chemical source having a high vaporization temperature is provided. The thin film deposition apparatus includes a chamber for depositing a thin film on a wafer, a canister for accommodating a liquid chemical source to be supplied to the chamber, and a vaporizer for vaporizing the liquid chemical source bubbled in the canister and providing the vaporized chemical source to the chamber. The vaporizer is installed on a top surface or lateral surface of the chamber by an adaptor block to be incorporated into the chamber. A first gas line between the vaporizer and the chamber is formed within the adaptor block.

### CROSS-REFERENCE TO RELATED PATENT APPLICATIONS

This application claims the benefit of Korean Patent Application No. 10-2004-0090130, filed on Nov. 6, 2004, in the Korean Intellectual Property Office, the disclosure of which is incorporated herein in its entirety by reference.

### BACKGROUND OF THE INVENTION

1. Field of the Invention

The present invention relates to a thin film deposition apparatus, and more particularly, to a thin film deposition apparatus that can use chemical sources having high vaporization temperatures.

2. Description of the Related Art

FIG. 1 is a schematic block diagram of a structure of a conventional thin film deposition apparatus. Referring to FIG. 1, the conventional thin film deposition apparatus includes a chamber 10 for depositing a thin film on a wafer, a canister 30 for accommodating a liquid chemical source to be supplied to the chamber 10, and a vaporizer 20 for vaporizing the liquid chemical source bubbled in the canister 30 and providing the vaporized chemical source to the chamber 10.

A first gas line L1 connected to the vaporizer 20 and a second gas line L2 through which a reactant gas to react the vaporized chemical source is provided are connected to the chamber 10. A first purge gas line L1′ and a second purge gas line L2′ through which inert gases are provided as purge gases are connected to the first and second gas lines L1 and L2, respectively. The first and second purge gas lines L1′ and L2′ are connected to an exhaust line 11 through which gas within the chamber 10 is exhausted.

A plurality of solenoid-type process valves V, operating according to an electrical signal, are installed in the first and second gas lines L1 and L2 and the first and second purge gas lines L1′ and L2′ to control the flow of the chemical source, the reactant gas, or the purge gases.

A thin film deposition apparatus, such as, a CVD or MOCVD apparatus, uses tetra-ethyl-ortho-silicate (TEOS) to form an oxide thin film on a wafer or uses a liquid source, such as, TiCl₄, to form a TiN thin film on the wafer. Liquid sources, such as, TEOS or TiCl₄, have low vaporization temperatures that are lower than 150 degrees and are vaporized by the vaporizer 20. The vaporized liquid sources are introduced into a chamber via process valves V.

However, SrxTiyOz (STO) and (Ba₁₋ₓ, Srₓ)TiO₃ (BST) which are recently and actively studied as a material for a dielectric thin film, require high vaporization temperatures, which are more than 250 degrees. Accordingly, the first gas line L1 between the vaporizer 20 and the chamber 10 and the process valve V installed in the first gas line L1 should keep a temperature equal to or greater than the temperature of the liquid source which is vaporized by the vaporizer 20. This is because such liquid sources requiring high vaporization temperatures, such as, STO or BST, are very sensitive to a temperature condition. For example, if a liquid source requiring a high vaporization temperature passes through a region whose temperature is lower than the vaporization temperature, the liquid source is, for example, condensed and not sufficiently vaporized. If a liquid source is condensed or not sufficiently vaporized, a desired thin film cannot be obtained, and the thin film deposition apparatus is contaminated, leading to a degradation of the reliability thereof.

In most cases, the process valve V installed between the vaporizer 20 and the chamber 10 is a solenoid type valve that operates under an electrical control. Such a solenoid-type process valve has an electrically operable component built therein. Thus, a temperature condition of the process valve V should be less than 150 degrees. A process valve operating at 250 degrees or more should include a cooler or the like. Hence, the process valve operating at 250 degrees or more is several times larger than a conventional process valve that operates at no more than 150 degrees. Thus, there are many restrictions in using the process valve operating at 250 degrees or more in a thin film deposition apparatus having a small space.

Furthermore, it is difficult in practice to heat the gas line installed between the vaporizer 20 and the chamber 10 to a temperature of 250 degrees or more.

### SUMMARY OF THE INVENTION

The present invention provides a thin film deposition apparatus having an improved structure to effectively use a chemical source which requires a high vaporization temperature, such as, STO and BST.

According to an aspect of the present invention, there is provided a thin film deposition apparatus including: a chamber for depositing a thin film on a wafer; a canister for accommodating a liquid chemical source to be supplied to the chamber; and a vaporizer for vaporizing the liquid chemical source bubbled in the canister and providing the vaporized chemical source to the chamber. The vaporizer is installed on a top surface or lateral surface of the chamber by an adaptor block to be incorporated into the chamber. A first gas line between the vaporizer and the chamber is formed within the adaptor block.

A heater is installed within the adaptor block to directly heat the first gas line.

Manual valves for supplying and purging a gas are directly installed within the adaptor block.

### BRIEF DESCRIPTION OF THE DRAWINGS

The above and other features and advantages of the present invention will become more apparent by describing in detail exemplary embodiments thereof with reference to the attached drawings in which:

FIG. 1 is a schematic block diagram of a structure of a conventional thin film deposition apparatus;

FIG. 2 is a schematic block diagram of a structure of a thin film deposition apparatus according to an embodiment of the present invention; and

FIG. 3 illustrates a structure of an adaptor block installed in a chamber shown in FIG. 2.

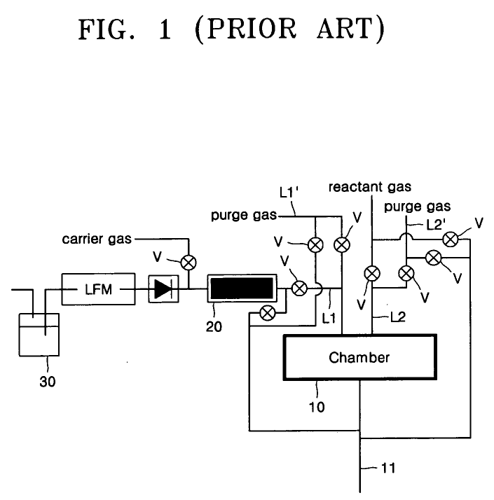

### DETAILED DESCRIPTION OF THE INVENTION

The present invention will now be described more fully with reference to the accompanying drawings, in which exemplary embodiments of the invention are shown.

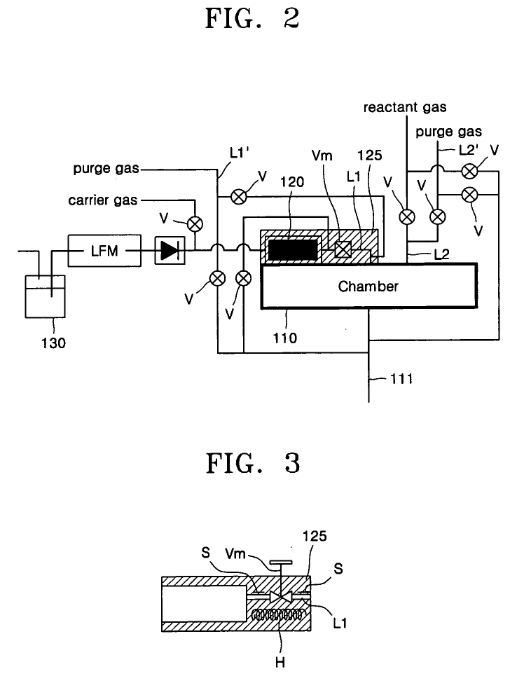

As shown in FIG. 2, a thin film deposition apparatus according to an embodiment of the present invention includes a chamber 110 for depositing a thin film on a wafer, a canister 130 for accommodating a liquid chemical source to be supplied to the chamber 1 10, and a vaporizer 120 for vaporizing the liquid chemical source bubbled in the canister 130 and providing the vaporized chemical source to the chamber 110.

A first gas line L1 connected to the vaporizer 120 and a second gas line L2 through which a reactant gas to react the vaporized chemical source is provided are connected to the chamber 110. A first purge gas line L1′ and a second purge gas line L2′ through which inert gases are provided as purge gases are connected to the first and second gas lines L1 and L2, respectively. An exhaust gas 111 through which gas within the chamber 110 is exhausted is connected to the first and second purge gas lines L1′ and L2′.

A plurality of solenoid-type process valves V, operating according to an electrical signal, are installed in the first and second gas lines L1 and L2 and the first and second purge gas lines L1′ and L2′ to control the flow of the chemical source, the reactant gas, or the purge gas.

According to an aspect of the present invention, the vaporizer 120 and the first gas line L1 are installed on an upper side or lateral side of the chamber 110 by an adaptor block 125 to be incorporated into the chamber 110. More specifically, as shown in FIG. 3, the adaptor block 125, made of stainless steel (SUS) or ceramic, is processed to form the vaporizer 120 therein. The first gas line L1 is a path formed by processing the inside of the adaptor block 125.

Heaters H are installed in the adaptor block 125. Since the adaptor block 125 directly heats the first gas line L1 using the heaters H, the thin film deposition apparatus of FIG. 2 can reduce thermal loss compared with a conventional thin film deposition apparatus in which a gas line is heated by a heating tape or a jacket.

Since the gas line in the conventional thin film deposition apparatus is surrounded by the heating tape or the jacket, the heating tape or the jacket may be deteriorated at a high temperature or a fire may be caused due to the deterioration. However, the first gas line L1 in the thin film deposition apparatus of FIG. 2 is heated by the heaters H installed within the adaptor block 125, which is made of metal or ceramic, so that the possibility of deterioration or fire may be removed.

As shown in FIG. 2, only one manual valve Vm for maintenance is installed in rear of the vaporizer 120. The manual valve Vm is not a solenoid type process valve but a manually operable valve. Thus, the manual valve Vm operates without obstructions of temperature conditions.

A feeding process valve V or a bypassing process valve V of the first purge gas line L1′ is installed in front of the adaptor block 125 to reduce the temperature of the valve V.

The feeding or bypassing process valve V may be directly installed on the adaptor block 125. In this case, unnecessary gas lines are removed.

A temperature sensor S for sensing the internal temperature of the first gas line L1 is installed within the adaptor block 125. The temperature sensor S may be organically connected to a temperature controller (not shown). In this case, when the internal temperature of the first gas line L1 departs from a predetermined temperature range, the temperature sensor S senses the internal temperature and sends a signal corresponding to the sensed temperature to the temperature controller. The temperature controller controls the heaters H according to the received signal so that the internal temperature of the first gas line L1 can be always within the predetermined range. Since the temperature sensor is well known in the art, detailed descriptions thereof will be omitted.

According to this structure, process valves operating at 150 degrees or less can be used because a chemical source that requires a vaporization temperature of 250 degrees or more, such as, STO or BST, passes through no process valves. Accordingly, the possibility that process valves used are damaged due to a long use and a high temperature is removed, thus improving process reproducibility and hardware stability. Thus, the machine availability can be increased.

As described above, in a thin film deposition apparatus according to the present invention, a vaporizer is incorporated into a chamber by using an adaptor block, a first gas line is formed within the adaptor block, and a heater for heating the first gas line is installed within the adaptor block. Thus, a chemical source having a high vaporization temperature, such as, STO or BST, can be used to form a thin film on a wafer.

Furthermore, since the heater is installed within the adaptor block and heats the first gas line, the possibility that the first gas line is deteriorated at a high temperature or that the first gas line is on fire can be removed.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A thin film deposition apparatus comprising:
a chamber for depositing a thin film on a wafer;
a canister for accommodating a liquid chemical source to be supplied to the chamber; and
a vaporizer for vaporizing the liquid chemical source bubbled in the canister and providing the vaporized chemical source to the chamber,
wherein the vaporizer is installed on a top surface or lateral surface of the chamber by an adaptor block to be incorporated into the chamber, and a first gas line between the vaporizer and the chamber is formed within the adaptor block.

2. The thin film deposition apparatus of claim 1, wherein a heater is installed within the adaptor block to directly heat the first gas line.

3. The thin film deposition apparatus of claim 1, wherein manual valves for supplying and purging a gas are directly installed within the adaptor block.
